(19) United States
(12) Patent Application Publication
(10) Pub. No.: US 2014/0327023 A1
(43) Pub. Date: Nov. 6, 2014

(54) PHOSPHOR ASSEMBLY FOR LIGHT EMITTING DEVICES

(71) Applicant: General Electric Company, (US)

(72) Inventors: Megan Marie Brewster, Albany, NY (US); Anant Achyut Setlur, Niskayuna, NY (US); Robert Joseph Lyons, Burnt Hills, NY (US); James Edward Murphy, Niskayuna, NY (US); Florencio Garcia, Schenectady, NY (US)

(73) Assignee: General Electric Company, Schenectady, NY (US)

(21) Appl. No.: 13/875,534

(22) Filed: May 2, 2013

(51) Int. Cl. H01L 33/50

(52) U.S. Cl. CPC H01L 33/504
USPC 257/98; 438/29

(57) ABSTRACT

A method for fabricating a light emitting device is disclosed. The light emitting device includes a light emitting diode (LED). The method includes disposing a layered phosphor composite or a thick phosphor composite radiationally coupled to the LED to form a light emitting device. The layered phosphor composite includes a first phosphor layer including a yellow-emitting phosphor over a second phosphor layer including manganese-doped potassium fluorosilicate (PFS). The second phosphor layer is disposed closer to the LED. The mass of the PFS of this light emitting device is at least 15% less than mass of the PFS in a reference light emitting device that has the same color temperature as the above mentioned light emitting device, but includes a blend of PFS and the yellow emitting phosphor instead of a layered configuration or has a decreased thickness.

### BACKGROUND

The present invention generally relates to a light emitting device. More particularly, the present invention relates to the assembly of phosphor powders in a light emitting device including a light emitting diode (LED).

Light emitting diodes (LEDs) are semiconductor light emitters often used as a replacement for other light sources, such as incandescent lamps. The color of light produced by an LED is dependent on the type of semiconducting material used in its manufacture. Colored semiconductor light emitting devices, including light emitting diodes and lasers (both are generally referred to herein as LEDs), have been produced from Group III-V alloys such as gallium nitride (GaN). In the GaN-based LEDs, light is generally emitted in the UV and/or blue range of the electromagnetic spectrum.

In one technique of converting the light emitted from LEDs to useful light, the LED is coated or covered with a phosphor layer. Some phosphors emit radiation in the visible portion of the electromagnetic spectrum in response to excitation by the electromagnetic radiation.

By interposing a phosphor excited by the radiation generated by the LED, light of different wavelengths in the visible range of the spectrum may be generated. Colored LEDs are often in demand to produce custom colors and higher luminosity. In addition to colored LEDs, a combination of LED generated light and phosphor generated light may be used to produce white light. The most popular white LEDs consist of blue emitting GaInN chips. The blue emitting chips are coated with a phosphor that converts some of the blue radiation to a complimentary color, e.g. a yellow-green emission or a combination of yellow-green and red emission. Together, the blue, yellow-green, and red radiation produces a white light. There are also white LEDs that utilize a UV emitting chip and a phosphor blend including red, green and blue emitting phosphors designed to convert the UV radiation to visible light.

Phosphors often include rare earth elements. Worldwide concentrated deposits of rare earth compounds are limited leading to scarcity and high cost for the materials. The cost of the phosphors used to produce white light in a LED device is a very significant part of the device price. Therefore, there is a need for reduction in phosphor mass without reducing the light quality and efficiency of the device in which the phosphors are used.

### BRIEF DESCRIPTION

In one embodiment, a method for fabricating a light emitting device is disclosed. The light emitting device includes a light emitting diode (LED). The method includes disposing a layered phosphor composite radiationally coupled to the LED to form a light emitting device. The layered phosphor composite includes a first phosphor layer including a yellow-emitting phosphor over a second phosphor layer including manganese-doped potassium fluorosilicate (PFS). The second phosphor layer is disposed closer to the LED. The mass of the PFS of this light emitting device is at least 15% less than mass of the PFS in a reference light emitting device that has the same color temperature as the above mentioned light emitting device, but includes a blend of PFS and the yellow emitting phosphor instead of a layered configuration.

In one embodiment, a method for fabricating a light emitting device is disclosed. The light emitting device includes a light emitting diode (LED). The method includes disposing a phosphor composite radiationally coupled to the LED, to form a light emitting device such that the phosphor composite includes a matrix material and a phosphor including manganese-doped potassium fluorosilicate (PFS). The disposed phosphor composite has a thickness in the range from about 50 microns to about 5 millimeters, and the mass of the phosphor is at least 15% less than mass of the phosphor in a reference light emitting device that has the same color temperature as the above-mentioned light emitting device, but with a phosphor composite thickness less than about 15 microns.

In another embodiment, a method for fabricating a light emitting device including a light emitting diode (LED) is disclosed. The method includes forming a first phosphor layer having a yellow-emitting phosphor in a silicone matrix; partially curing the first layer; forming a second phosphor layer having manganese-doped potassium fluorosilicate (PFS) in a silicone matrix; curing the first and second layers together; and disposing the cured first and second layers remotely on the LED, such that the second layer is disposed closer to the LED than the first layer.

### DRAWINGS

These and other features, aspects, and advantages of the present invention will become better understood when the following detailed description is read with reference to the accompanying drawing, wherein:

FIG. 1 is a schematic cross-sectional view of a light emitting device;

FIG. 2 is a schematic cross-sectional view of a light emitting device, in accordance with one embodiment of the present invention;

FIG. 3A depicts cross-sectional view of a phosphor layer arrangement in a thick configuration, in accordance with one embodiment of the present invention;

FIG. 3B depicts cross-sectional view of a phosphor layer arrangement in a thin configuration, in accordance with one embodiment of the present invention;

FIG. 3C depicts cross-sectional view of a phosphor layer arrangement in a layered configuration with the yellow-emitting phosphor closer to the LED, in accordance with one embodiment of the present invention;

FIG. 3D depicts cross-sectional view of a phosphor layer arrangement in a layered configuration with the red-emitting phosphor closer to the LED, in accordance with one embodiment of the present invention; and

FIG. 4 depicts the color coordinates of the different configurations of examples shown in FIGS. 3A, 3B, 3C, and 3D.

### DETAILED DESCRIPTION

Embodiments of the present invention include the methods for arranging a phosphor in a light emitting device such that the mass of any required phosphor can be lowered.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

In the following specification and the claims that follow, the singular forms “a”, “an” and “the” include plural referents unless the context clearly dictates otherwise.

A phosphor is a luminescent material that absorbs radiation energy in a portion of the electromagnetic spectrum and emits energy in another portion of the electromagnetic spectrum. A phosphor material may convert UV or blue radiation to a lower energy visible light. The color of the generated visible light is dependent on the phosphor materials used. The phosphor may include only a single phosphor material or two or more phosphors of basic color, for example, a particular mix with one or more of a yellow and red phosphor to emit a desired color (tint) of light.

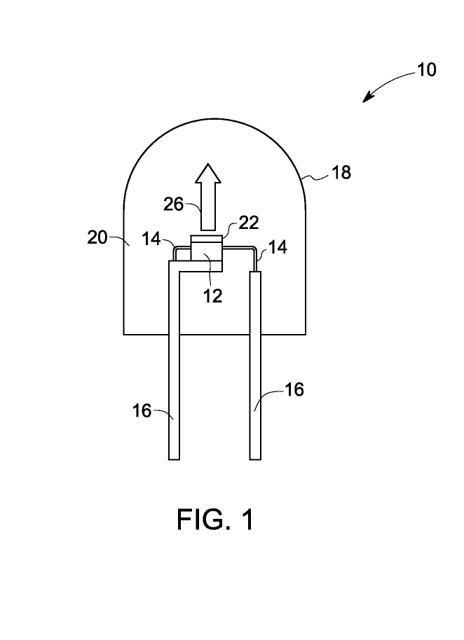

With reference to FIG. 1, a light emitting device 10 is shown in accordance with one embodiment of the present invention. Light emitting device 10 comprises a semiconductor UV or blue radiation source, such as a light emitting diode (LED) chip 12 and leads 14 electrically attached to the LED chip. The leads 14 may comprise thin wires supported by a thicker lead frame(s) 16 or the leads may comprise self-supported electrodes and the lead frame may be omitted. The leads 14 provide current to the LED chip 12 and thus cause the LED chip 12 to emit radiation.

The lamp may include any semiconductor blue or UV light source that is capable of producing white light when the radiation emitted from it is directed onto the phosphor. In some embodiments, the semiconductor light source is a blue emitting LED doped with various impurities. Thus, the LED may be a semiconductor diode based on any suitable III-V, II-VI or IV-IV semiconductor layers and having an emission wavelength of about 250 to 550 nm. In particular, the LED may contain at least one semiconductor layer comprising GaN, ZnSe, or SiC. For example, the LED may comprise a nitride compound semiconductor represented by the formula InᵢGaⱼAlₖN (where 0≦i; 0≦j; 0≦k and i+j+k=1) having an emission wavelength greater than about 250 nm and less than about 550 nm. In particular, the chip may be a near-UV or blue emitting LED having a peak emission wavelength from about 400 to about 500 nm. Such LED semiconductors are known in the art. The radiation source is described herein as an LED for convenience. However, as used herein, the term is meant to encompass all semiconductor radiation sources including, for example, semiconductor laser diodes.

The LED chip 12 may be encapsulated within a shell 18, which encloses the LED chip and an encapsulant material 20. The shell 18 may be, for example, glass or plastic. Preferably, the LED chip 12 is substantially centered in the encapsulant 20. The encapsulant material 20 is preferably an epoxy, plastic, low temperature glass, polymer, thermoplastic, thermoset material, resin, silicone, or other type of LED encapsulating material as is known in the art. Optionally, the encapsulant 20 is a spin-on glass or some other high index of refraction material. The encapsulant material 20 may be an epoxy or a polymer material, such as silicone. Both the shell 18 and the encapsulant 20 are preferably transparent or substantially optically transmissive with respect to the wavelength of light produced by the LED chip 12, and further with respect to the wavelength of light produced by a combination of LED chip 12 and a phosphor 22.

As used herein, the term “phosphor” is intended to include both a single phosphor material, and a group of phosphor materials. Further, the phosphor 22 may include one or more phosphor materials or an arrangement of two or more phosphor materials in a particular order. As used herein, a “phosphor material” is a specific compound emitting light in the visible region by absorbing energy in the UV or visible region. The phosphor may include one or more different phosphor materials. For example, a red phosphor may include one or more different phosphor materials emitting in the red wavelength region.

Alternately, the light emitting device 10 may only include an encapsulant material without an outer shell 18. The LED chip 12 may be supported, for example, by the lead frame 16, by the self-supporting electrodes, the bottom of the shell 18, or by a pedestal (not shown) mounted to the shell or to the lead frame. In some embodiments, the LED chip 12 is mounted in a reflective cup (not shown). The cup may be made from or coated with a reflective material, such as alumina, titania, or other dielectric powder known in the art. An example of a reflective material is alumina.

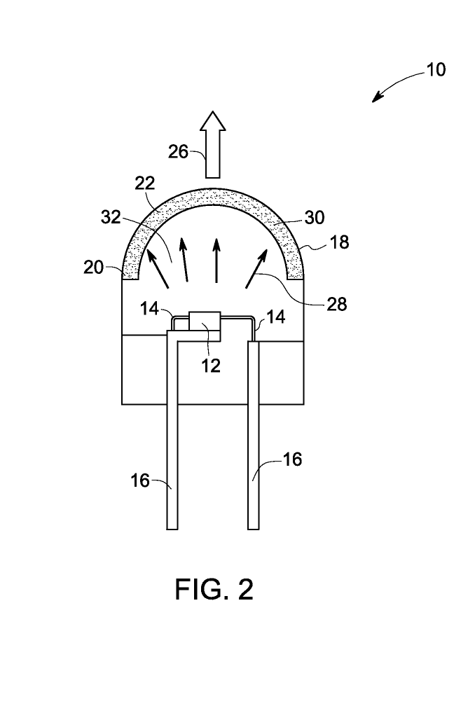

The phosphor 22 may be interspersed within the encapsulant material 20. The phosphor (in the form of a powder) may be interspersed within a single region (not shown) of the encapsulant material 20 or, throughout the entire volume of the encapsulant material. The UV/blue radiation from the LED chip 12 may be completely or partially absorbed by the phosphor 22 and re-emitted in the visible region. In one embodiment, the phosphor 22 is arranged remotely in the vicinity of the LED. As defined herein ‘remotely’ means that there is no direct physical contact. Thus, the phosphor 22 is not in direct physical contact with the LED chip 12, but is radiationally coupled to the LED chip 12. As used herein, “radiationally coupled” means that at least a part of the radiation 28 from the LED chip 12 is absorbed by the phosphor 22. The phosphor 22 partially absorbs the light emitted by the LED chip 12, the emitted light from the phosphor may be mixed with the unabsorbed light emitted by the LED chip 12 and appear as the white light 26 from the light emitting device 10. In one specific embodiment shown in FIG. 2, the phosphor 22 is mixed with an encapsulant material 20 to form a phosphor composite 30. The phosphor composite 30 may include the phosphor 22 in the form of powder, and the encapsulant material as a matrix. The matrix material may include silicone, polymer, glass, or any combination of these. In one embodiment, the phosphor composite 30 is arranged remotely in the vicinity of the LED. In this embodiment, the encapsulant material 20 may cover only a portion of the volume, where the phosphor composite 30 is formed. The volume 32 between the LED chip 12 and the phosphor composite 30 may be filled by air or vacuum.

In one embodiment, the phosphor 22 is assembled in the light emitting device 10 in a particular configuration. Assembling the phosphor 22 in different configurations than hereby known configurations is found to reduce the required mass of some or all phosphors for emitting a light of certain quality. The configuration of assembling the phosphor may include the variation in the thickness of the phosphor composite 30 in the system 10, arranging the phosphors in a layered configuration in the composite 30, or both the variation in thickness and the layered arrangement.

In one configuration, the thickness of the phosphor composite 30 in a light emitting device 10 is greater than a phosphor composite in a similar light emitting device having the phosphor 22 and LED chip 12. When the thickness of the phosphor composite 30 is increased, the total mass of the phosphor 22 that is required to absorb a fixed amount of LED radiation and reach a specific color point is significantly reduced. In this embodiment, there is no change in the emitted light quality (color point, color rendering index (CRI) and efficiency) even for a significant reduction in phosphor usage. This observation is quite unexpected as, generally, the total amount of absorbed LED radiation and emitted radiation by the phosphor should only be dependent upon the total mass of phosphor 22 within the phosphor composite 30.

In one embodiment, the ratio of mass of the phosphor 22 to the thickness of the phosphor encapsulated in the encapsulant material 20 is in a range from about 150 mg/mm to about 630 mg/mm. Where a silicone material is used as a matrix, the phosphor composite 30 has a phosphor 22 dispersed in a thickness ranging from about 50 microns to about 5 millimeters using about 20 weight % lesser phosphor than that required for obtaining the same light quality in a thinner phosphor composite of the light emitting device 10. If mass of the phosphor 22 is “M” in the phosphor composite 30 of constant face area A, and the thickness is “T”, in one embodiment, the density M/(AT) of the phosphor 22 is in a range from about 0.25 g/cm³ to about 1.10 g/cm³. Further, the density M/AT may be in the range from about 0.25 g/cm³ to about 0.75 g/cm³.

Phosphor composite 30 may include more than one phosphor 22, each emitting light of a different wavelength. Phosphor 22 may be evenly distributed in the phosphor composite 30, or may be arranged in a graded configuration.

In one embodiment, the phosphor composite 30 is a specific arrangement of different phosphors. In an exemplary embodiment, the phosphor composite 30 includes more than one layer, each layer having at least one phosphor. The phosphor composite 30 may be in a layered form having at least two layers, for example, a first layer (not shown) and a second layer (not shown). The phosphors of first and second layers combine together to form the phosphor 22 of phosphor composite 30. The first layer may have a first phosphor and the second layer may have a second phosphor. In one embodiment, the phosphor composite 30 includes the first phosphor that is configured to absorb energy from LED chip 12 and emit in a wavelength range that is different from the emission wavelength range of the second phosphor absorbing energy from the LED chip 12. For example, the first phosphor layer may have a red emitting phosphor including one or more red emitting phosphor materials. Similarly, the second phosphor layer may have a yellow or yellow-green emitting phosphor including one or more yellow or green-emitting phosphor materials. In one embodiment, the first phosphor layer substantially covers the second phosphor layer such that the light emitted by the second phosphor layer passes through the first phosphor layer.

In one embodiment, the second layer including the second phosphor is closer to the LED chip 12 than the first layer including the first phosphor. The second phosphor may emit a light of longer wavelength as compared to the first phosphor emitting a light of shorter wavelength. Alternately, the second phosphor may emit a light of shorter wavelength as compared to the first phosphor emitting a light of longer wavelength. In one embodiment, the first phosphor emits in a red region by absorbing energy from a blue LED chip 12, and the second phosphor emits in a yellow or green region by absorbing energy from the LED chip 12. Alternately, the first phosphor may emit in a yellow or green region and the second phosphor may emit in a red region, by absorbing energy from the blue LED chip 12.

The green or yellow emitting phosphor material may include one or more europium doped or cerium doped rare earth element oxides or oxynitride phosphors. Examples of suitable materials include (Sr,Ba,Ca)₂SiO₄:Eu²⁺, (Y,Lu,Gd,Tb)₃(Al,Ga)₅O₁₂:Ce³⁺, (Ca,Lu)₃(Sc,Mg)₂Si₃O₁₂:Ce³⁺, and (Sr,Ca)₃(Al,Si)O₄(F,O):Ce³.

The red emitting phosphor material may include a Mn⁴⁺-doped complex fluoride phosphor. Examples of Mn⁴⁺-doped phosphors include K₂[SiF₆]:Mn⁴⁺, K₂[TiF₆]:Mn⁴⁺, K₂[SnF₆]:Mn⁴⁺, Cs₂[TiF₆], Rb₂[TiF₆], Cs₂[SiF₆], Rb₂[SiF₆], Na₂[TiF₆]:Mn⁴⁺, Na₂[ZrF₆]:Mn⁴⁺, K₃[ZrF₇]:Mn⁴⁺, K₃ [BiF₆]:Mn⁴⁺, K₃[YF₆]:Mn⁴⁺, K₃[LaF₆]:Mn⁴⁺, K₃[GdF₆]:Mn⁴⁺, K₃[NbF₇]:Mn⁴⁺, K₃[TaF₇]:Mn⁴⁺. In a particular embodiment, the red-emitting phosphor is manganese-doped potassium fluorosilicate with the formula K₂SiF₆:Mn^{4+.}

The median particle size of the phosphor particles as measured by light scattering may be from about 0.1 microns to about 80 microns. The phosphor materials described herein are commercially available, or methods of preparing the phosphor materials is described in literature, for example, through solid-state reaction methods by combining, for example, elemental oxides, carbonates, and/or hydroxides as starting materials.

When the first and second phosphors are arranged in a layered manner, a lesser amount of phosphor mass is required to emit a light of particular color point and CRI with an equivalent efficacy when compared to arranging the first and second phosphors blended together in the phosphor composite 30. Thus, the total mass of the first and second phosphors in two separate layers is less than the total mass of the blend of first and second phosphor s in a single layer.

In a particular embodiment, it was further found that, when laid in a layered form, the mass of the second phosphor in the second layer (that is closest to the LED chip 12) may be significantly reduced compared to the mass of the second phosphor in a phosphor blend, without causing any change in the color quality and efficacy of the composite 30. Further, the required mass of the first phosphor in the first layer may be slightly increased, and the mass of the second phosphor in the second layer may be significantly reduced, as compared to a phosphor blend, without having any observable change in the light quality or efficacy of lighting systems using the phosphor composite 30.

In general, the ratio of each of the individual phosphors in the phosphor composite 30 may vary depending on the characteristics of the desired light output. The relative proportions of the individual phosphors in the various embodiment may be adjusted such that when their emissions are blended and employed in an LED lighting device, there is produced visible light of predetermined x and y values on the CIE chromaticity diagram. As stated, a white light is preferably produced. This white light may, for instance, possess an x value in the range of about 0.30 to about 0.55, and a y value in the range of about 0.30 to about 0.55. In one embodiment, a ratio of the mass of the first phosphor to the mass of the second phosphor in the device 10 is greater than the ratio in a light emitting device 10 comprising the first and second phosphors in a blend form in the phosphor composite.

In one embodiment, in a device having a phosphor composite 30 with first and second layers having first and second phosphors respectively, the mass of the second phosphor is at least 20% less than the mass of the second phosphor in a light emitting device having the first and second phosphors in a blend form in the phosphor composite. In one embodiment, more than one matrix may be used in layering the phosphor composite 30 in the light emitting device 10. Further, the first and second layers may have different matrices along with having different phosphors.

Phosphor composite 30 may be deposited in the light emitting device 10 by any appropriate method. For example, a suspension of the phosphor(s) may be formed, and applied as a phosphor layer to the shell 18 of the light emitting device 10. In one such method, a silicone slurry in which the phosphor particles are suspended in the matrix is coated on the shell 18 around the LED. Both the shell 18 and the matrix may be transparent to allow visible light to be transmitted through those elements.

In one method of fabricating a light emitting device of layered phosphor composite 30, a LED is mounted using the leads 14, and the first and second phosphor layers are deposited remotely around the LED. If the phosphor 22 is to be interspersed within the material of matrix, then a phosphor 22 may be added to a polymer precursor, the precursor may be cured, and the phosphor composite can then be placed around LED chip 12 remotely.

In one embodiment, a first layer of a composite 30 including a first phosphor is mixed with a matrix material, and deposited over the inside part of the shell 18 and partially cured. A second layer of the composite 30 comprising a second phosphor in the matrix may be deposited on the partially cured first phosphor layer, and then the first and second phosphor layers may be cured together. The first and second layers may be disposed such that the second layer is arranged closest to the LED than the first layer or vice versa. Other known phosphor interspersion methods, such as transfer loading, may also be used.

### EXAMPLES

The following examples illustrate methods, materials and results, in accordance with specific embodiments, and as such should not be construed as imposing limitations upon the claims. All components are commercially available from common chemical suppliers.

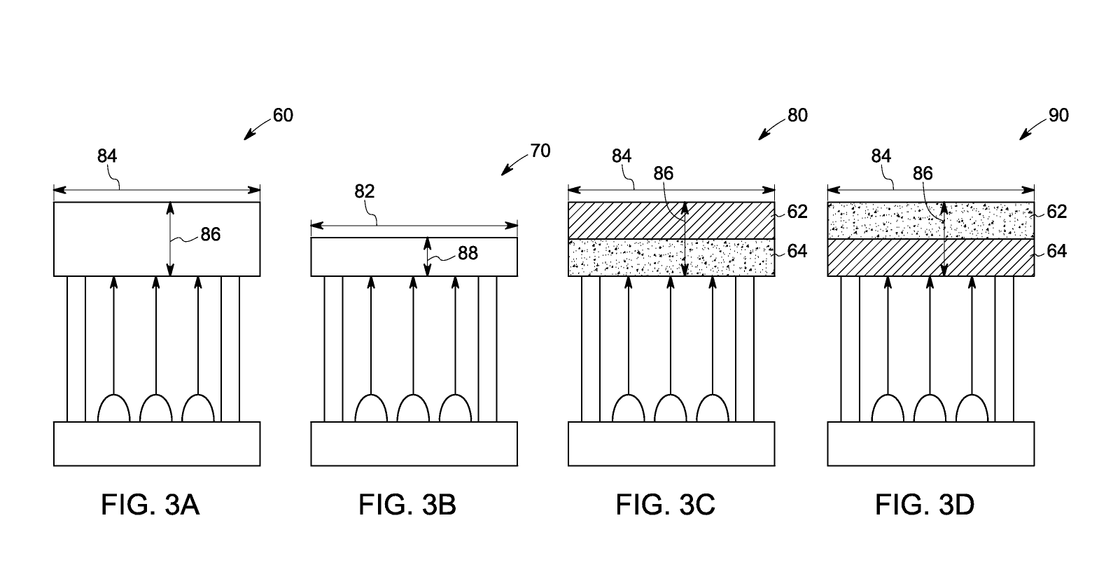

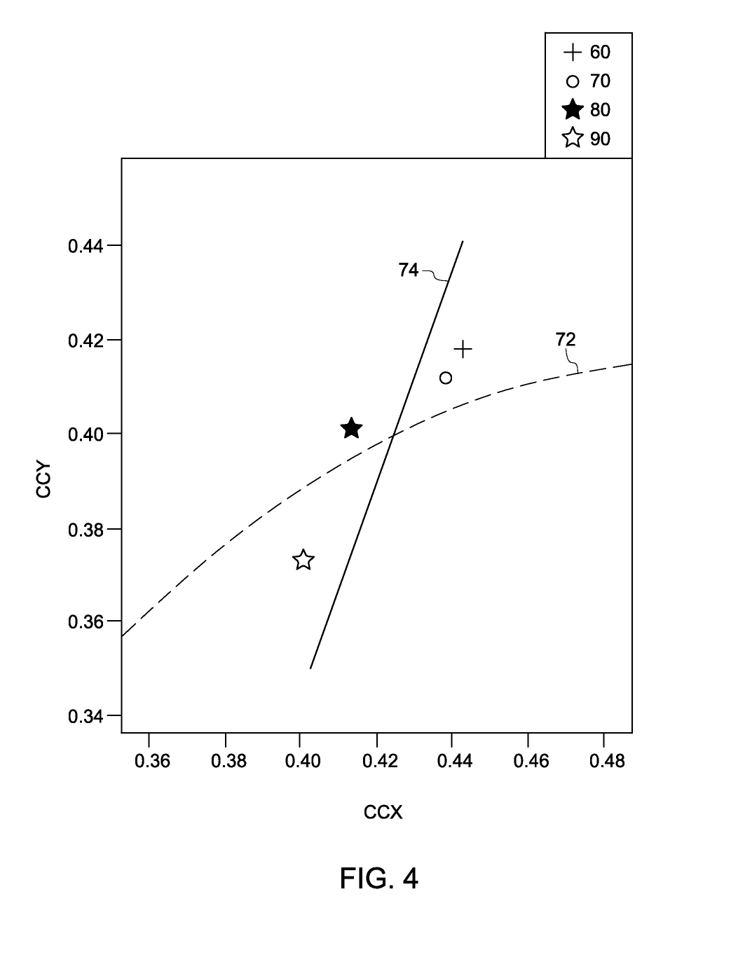

FIG. 3 (A, B, C, D) depict examples of some of the remote-phosphor configurations investigated. The phosphors used were the red-emitting K₂SiF₆:Mn⁴⁺ (PFS) and green/yellow-emitting (Sr,Ca)₃(Al,Si)O₄(F,O):Ce³⁺ (SASOF). Blends of these phosphors in a thick 60 (FIG. 3A) and thin 70 (FIG. 3B) configurations were compared. Further, layered configuration 80 (FIG. 3C) with the yellow-emitting phosphor closer to the LED and the layered configuration 90 (FIG. 3D) with red-emitting phosphor closer to the LED were compared. Thus, in the configuration 80, the first layer 62 contains the red-emitting phosphor and the second layer (closer to LED) 64 contains the yellow-emitting phosphor material. In the configuration 90, the yellow-emitting phosphor makes the first layer 62 and the red-emitting phosphor material makes the second layer (closer to LED) 64. The phosphors in the blend or layered form were incorporated in a silicone tape to make the phosphor composite 82. All the dimensions except thickness of the tape 82 were configured to be a constant in all the variations. The thickness 86 of the thick blend and the two layered configurations was 2.3mm, while the thickness 88 of the thin blend was 0.82 mm. In all the instances 60, 70, 80, 90, the amounts of the two phosphors were optimized to achieve a correlated color temperature (CCT) in the vicinity of about 3000 K with a distance from the black body (dbb) of less than 0.004. The color coordinates of the different instances are as shown in FIG. 4. The distance from the black body 72 and 3000K color temperature 74 lines are shown in FIG. 4 for reference.

Table 1 summarizes the experimental results of the configurations 60, 70, 80, and 90. The color temperature (CCT), distance from the black body (dbb), color rendering index (CRI) R₉ (a metric that indicates how well the light renders a deep shade of red), efficacy, and the amount of phosphor used in each configurations is listed in the table. The percentages show a percentage increase (+) or decrease (-) respect to the blend in the thin tape configuration 70. It was observed that the effect of phosphor layering or increasing the tape thickness can lead to reductions of up to about 45% in the required amount of the phosphor. In the case of layered phosphors, it is the layer that is closer to the LED (second layer) that shows significant mass reduction.

TABLE 1

| | Color quality | | | | | | | |
|---|---|---|---|---|---|---|---|---|
| | CCT | | | | Efficacy | Mass (mg) | | |
| Configuration | (K) | dbb | CRI | R₉ | (Lm/W) | PFS | SASOF | Total |
| Thin 70 | 3007 | 0.004 | 91 | 78 | 150 | 315 | 185 | 500 |
| (reference) | | | | | | | | |
| Thick 60 | 3040 | 0.003 | 90 | 74 | 152 | 223 | 137 | 360 |
| | | | | | (+1.3%) | (−29%) | (−26%) | (−28%) |
| LED/SASOF/ | 3412 | 0.003 | 93 | 85 | 166 | 505 | 103 | 608 |
| PFS 80 | | | | | (+10.6%) | (+60%) | (−44%) | (+22%) |
| LED/PFS/ | 3059 | −0.003 | 88 | 63 | 154 | 173 | 115 | 288 |
| SASOF 90 | | | | | (+2.7%) | (−45%) | (−38%) | (−42%) |

Therefore, very similar color temperature, dbb, and CRI may be obtained by using a lesser amount of phosphor in a phosphor composite by varying the structural alignment and / or the thickness of the phosphor composite. In other words, a higher efficacy may be obtained by using the same amount of phosphor material in a thicker phosphor composite form as compared to using in a thinner phosphor composite form. Further, by using a layered approach for the positioning of the phosphor materials in the light emitting system as compared to a blend, the required quality of light may be obtained by using a lesser amount (compared to a blend) of an expensive phosphor material by positioning that phosphor material closer to LED than the less-expensive phosphor material counterpart.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A method for fabricating a light emitting device comprising a light emitting diode (LED), said method comprising:
disposing a layered phosphor composite radiationally coupled to the LED to form a light emitting device, the layered phosphor composite comprising:
a first phosphor layer comprising a yellow-emitting phosphor over a second phosphor layer comprising manganese-doped potassium fluorosilicate (PFS); and
the second phosphor layer being disposed closer to the LED,
wherein mass of the PFS is at least 15% less than mass of the PFS in a reference light emitting device having the same color temperature as the light emitting device, and comprising a blend of PFS and the yellow emitting phosphor.

2. The method of claim 1, wherein the yellow-emitting phosphor comprises (Sr,Ba,Ca)₂SiO₄:Eu²⁺, (Y,Lu,Gd,Tb)₃(Al,Ga)₅O₁₂:Ce³⁺, (Ca,Lu)₃(Mg,Sc)₂Si₃O₁₂:Ce³⁺, (Sr,Ca)₃(Al,Si)O₄(F,O):Ce³⁺, or a combination thereof.

3. The method of claim 1, wherein the layered phosphor composite is disposed remotely over the LED.

4. The method of claim 1, wherein the layered phosphor composite further comprises a matrix material.

5. The method of claim 4, wherein the matrix material comprises silicone, polymer, glass, or a combination thereof.

6. The method of claim 1, wherein the mass of the PFS is at least 25% less than mass of the PFS in the reference light emitting device.

7. A device prepared using the method of claim 1.

8. A method for fabricating a light emitting device containing a light emitting diode (LED), said method comprising:
disposing a phosphor composite radiationally coupled to the LED, to form a light emitting device, the phosphor composite comprising:
a matrix material; and
a phosphor comprising manganese-doped potassium fluorosilicate (PFS),
wherein the phosphor composite has a thickness in the range from about 50 microns to about 5 millimeters, and the mass of the phosphor is at least 15% less than mass of the phosphor in a reference light emitting device having the same color temperature as the light emitting device and having a phosphor composite thickness less than about 15 microns.

9. The method of claim 8, wherein a density of phosphor in the phosphor composite is in a range from about 0.25 g/cm³ to about 1.10 g/cm³.

10. The method of claim 9, wherein the density is in a range from about 0.25 g/cm³ to about 0.75 g/cm³.

11. The method of claim 8, wherein the phosphor composite is disposed remotely over the light emitting diode.

12. The method of claim 8, wherein the phosphor is evenly distributed throughout the composite.

13. The method of claim 8, wherein the phosphor composite comprises more than one phosphor.

14. The method of claim 8, wherein the phosphor composite further comprises a yellow emitting phosphor.

15. A device prepared using the method of claim 8.

16. A method for fabricating a light emitting device, comprising a light emitting diode (LED), said method comprising:
forming a first phosphor layer comprising a yellow-emitting phosphor in a silicone matrix;
partially curing the first layer;
forming a second phosphor layer comprising manganese-doped potassium fluorosilicate (PFS) in a silicone matrix;
curing the first and second layers together; and
disposing the cured first and second layers remotely on the LED, the second layer being disposed closer to the LED than the first layer and radiationally coupled to the LED.

17. The method of claim 16, wherein a combined thickness of the first and second layer is in a range from about 50 microns to about 5 millimeters.

18. The method of claim 16, wherein a density of the phosphor in the phosphor composite is in a range from about 0.25 g/cm³ to about 0.75 g/cm³.

19. A device prepared using the method of claim 16.
